(19) United States
(12) Patent Application Publication
(10) Pub. No.: US 2026/0155334 A1
(43) Pub. Date: Jun. 4, 2026

(54) Method and Apparatus for Automated Regulation of a Frequency-Modulated Multilevel Outphasing Power Amplifier

(71) Applicant: Lam Research Corporation, Fremont, CA (US)

(72) Inventor: Sanghyeon Park, Sunnyvale, CA (US)

(21) Appl. No.: 18/706,353

(22) PCT Filed: Oct. 31, 2022
(86) PCT No.: PCT/US2022/048486

§ 371 Date: Apr. 30, 2024

Related U.S. Application Data
(60) Provisional application No. 63/275,397, filed on Nov. 3, 2021.

(51) Int. Cl. H01J 37/32

(52) U.S. Cl. CPC H01J 37/32174; H01J 37/32146; H01J 37/32935; H01J 37/3299

(57) ABSTRACT

A radiofrequency (RF) power supply system includes a plurality of RF inverters. Each of the RF inverters is configured to generate a sinusoidal RF signal from an input signal applied to one or more gates of one or more transistor devices. A controller is programmed to control an operation mode of the RF power supply system at a given time. The operation mode is defined by which of the RF inverters are on at the given time, which of the RF inverters are off at the given time, and which of the RF inverters are operated in accordance with a phase-shifted input signal at the given time. The controller is programmed to control an amount of phase-shift applied to the phase-shifted input signal at the given time to cause a combined output power of the plurality of RF inverters to substantially match a target power setting.

### BACKGROUND

Plasma processing systems are used to manufacture semiconductor devices, e.g., chips/die, on semiconductor wafers. In the plasma processing system, the semiconductor wafer is exposed to various types of plasma to cause prescribed changes to a condition of the semiconductor wafer, such as through material deposition and/or material removal and/or material implantation and/or material modification, etc. During plasma processing of the semiconductor wafer, radiofrequency (RF) power is transmitted through a process gas within a chamber to transform the process gas into the plasma in exposure to the semiconductor wafer. Reactive constituents of the plasma, such as radicals and ions, interact with materials on the semiconductor wafer to achieve a prescribed effect on the semiconductor wafer. In some plasma processing systems, generated RF power is transmitted to the process gas by way of an antenna positioned outside of the plasma processing chamber. It is within this context that embodiments described in the present disclosure arise.

### SUMMARY

In an example embodiment, an RF power supply system is disclosed. The RF power supply system includes a plurality of RF inverters. Each of the plurality of RF inverters is configured to generate a sinusoidal RF signal from an input signal applied to one or more gates of one or more transistor devices. The RF power supply system also includes a controller programmed to control an operation mode of the RF power supply system at a given time. The operation mode is defined by which of the plurality of RF inverters are on at the given time, which of the plurality of RF inverters are off at the given time, and which of the plurality of RF inverters are operated in accordance with a phase-shifted input signal at the given time. The controller is programmed to control an amount of phase-shift applied to the phase-shifted input signal at the given time to cause a combined output power of the plurality of RF inverters to substantially match a target power setting.

In another example embodiment, a method is disclosed for operating an RF power supply system. The method includes receiving a target power setting. The method also includes determining an operation mode of the RF power supply system that provides an RF power output range for the RF power supply system that includes the target power setting. The RF power supply system includes a plurality of RF inverters. Each of the plurality of RF inverters is configured to generate a respective sinusoidal RF signal from a respective input signal applied to one or more gates of one or more respective transistor devices. The operation mode is defined by which of the plurality of RF inverters are on at a given time, which of the plurality of RF inverters are off at the given time, and which of the plurality of RF inverters are operated in accordance with a phase-shifted input signal at the given time. The method also includes determining an amount of phase-shift for the phase-shifted input signal that causes a combined output power of the plurality of RF inverters to substantially match the target power setting. The method also includes directing the RF power supply system to operate in accordance with the determined operation mode and the determined amount of phase-shift for the phase-shifted input signal. In some embodiments, the method includes operating the RF power supply system in accordance with a negative feedback control loop in which a measurement of the combined output power of the plurality of RF inventers is used as a feedback signal to control the amount of phase-shift for the phase-shifted input signal, such that a difference between the measured combined output power of the plurality of RF inverters and the target power setting is minimized.

Other aspects and advantages of the embodiments will become more apparent from the following detailed description and the accompanying drawings.

### BRIEF DESCRIPTION OF THE DRAWINGS

FIG. 1A shows an RF power supply system connected to supply RF power to an antenna to drive a plasma load within a plasma processing chamber, in accordance with some embodiments.

FIG. 1B shows a schematic view of an RF inverter, in accordance with some embodiments.

FIG. 1C shows various ways in which RF inverters can be controlled at a given time by way of input signals, in accordance with some embodiments.

FIG. 1D shows an example vertical cross-section diagram of a plasma processing system, in accordance with some embodiments of the present disclosure.

FIG. 1E shows a top view of the antenna, in accordance with some embodiments.

FIG. 1F shows a diagram of the controller, in accordance with some example embodiments.

FIG. 2A shows an example of how the RF power supply system can be operated in accordance with multiple operation modes, in accordance with some embodiments.

FIG. 2B shows plots of the output RF power provided by the output RF signal for the three operational modes as a function of the phase shift angle applied to the outphased ones of the RF inverters, in accordance with some embodiments.

FIG. 2C shows plots of the output RF power provided by the output RF signal for the three operational modes, in accordance with some embodiments.

FIG. 3 shows an example RF power supply system corresponding to a particular implementation of the RF power supply system of FIG. 1A, in accordance with some embodiments.

FIG. 4A shows a table of example operational modes for the example RF power supply system of FIG. 3, in accordance with some embodiments.

FIG. 4B shows plots of the output RF power provided by the output RF signal for the operational modes of FIG. 4A for the example RF power supply system, in accordance with some embodiments.

FIG. 5A shows an example situation in which the target RF power setpoint falls within one of multiple operation modes of the RF power supply system, in accordance with some embodiments.

FIG. 5B shows an example situation in which the target RF power setpoint can be achieved by multiple operation modes of the RF power supply system, in accordance with some embodiments.

FIG. 5C shows an example of the controller operating to shift the RF power supply system between operation modes as the output RF power of the RF power supply system drifts upward with increasing temperature, in accordance with some embodiments.

FIG. 5D shows an example of the controller operating to shift the RF power supply system between operation modes as the output RF power of the RF power supply system drifts downward with decreasing temperature, in accordance with some embodiments.

FIG. 6A shows a chart that displays an example plasma load impedance operational window, in accordance with some embodiments.

FIG. 6B shows an example chart that illustrates the output RF power ranges for different viable operation modes at each of multiple impedance points within the plasma load impedance operational window of FIG. 6A, in accordance with some embodiments.

FIG. 7A shows a flowchart of a method for operating an RF power supply system, in accordance with some embodiments.

FIG. 7B shows a continuation of the method of FIG. 7A, in accordance with some embodiments.

FIG. 7C shows a further continuation of the methods of FIGS. 7A and 7B, in accordance with some embodiments.

### DETAILED DESCRIPTION

In the following description, numerous specific details are set forth in order to provide a thorough understanding of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

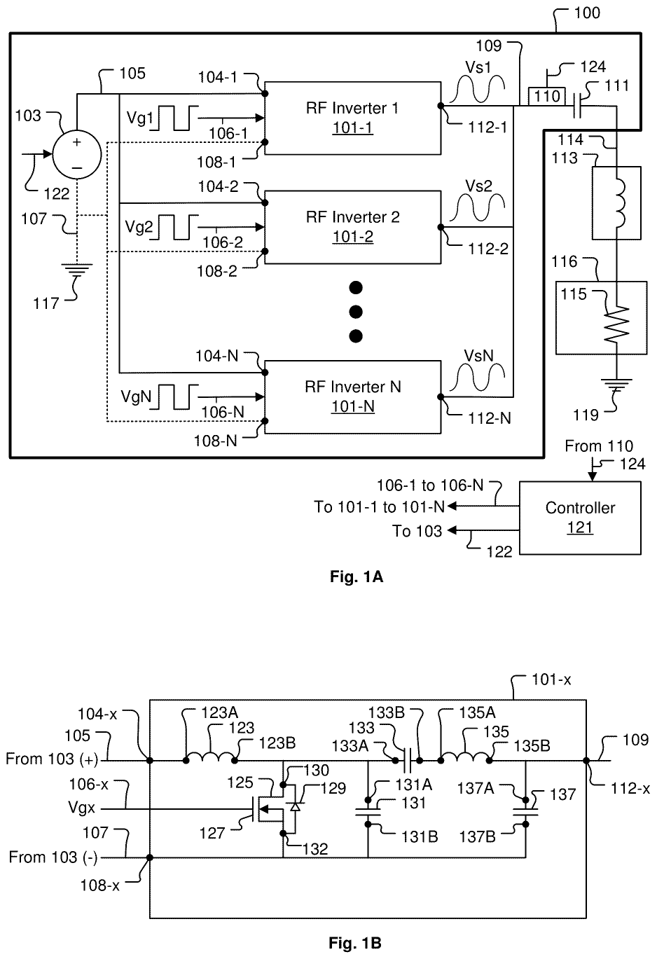

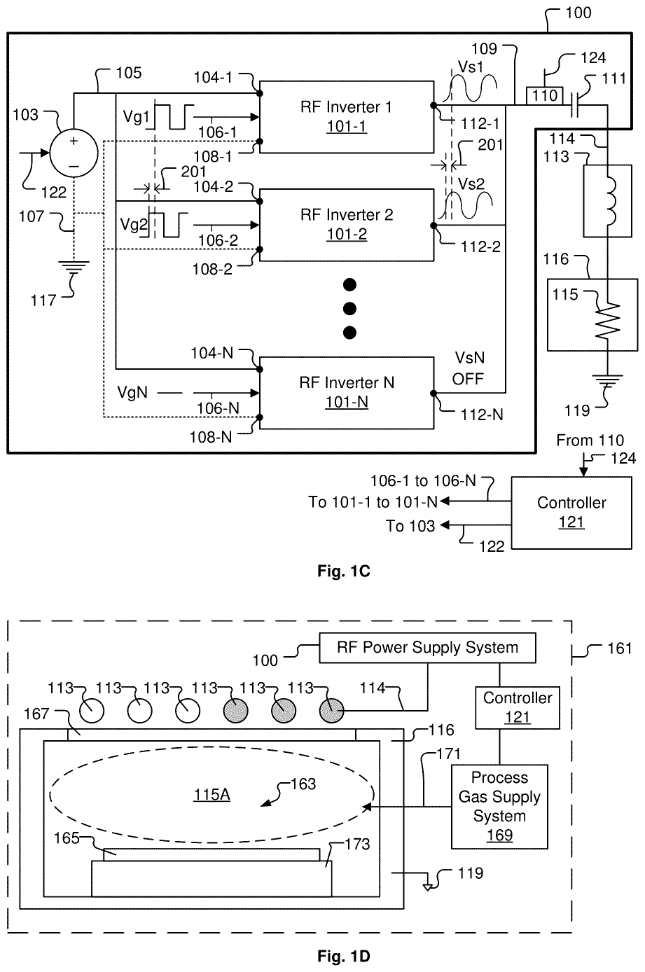

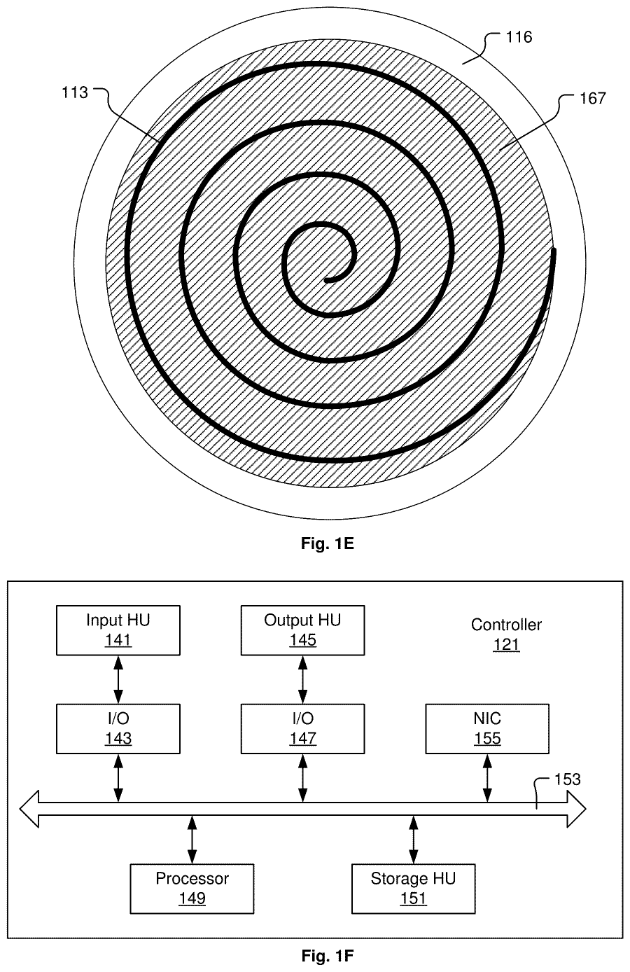

FIG. 1A shows an RF power supply system 100 connected to supply RF power to an antenna/electrode 113 to drive a plasma load 115 within a plasma processing chamber 116, in accordance with some embodiments. The RF power supply system 100 includes a number (N) of RF inverters 101-1 to 101-N, where N is greater than one. In some embodiments, each of the RF inverters 101-1 to 101-N is configured to generate a respective sinusoidal RF signal Vs1 to VsN from a respective input signal Vg1 to VgN that is applied to one or more gates 127 of one or more transistor devices 125 (see FIG. 1B) within the RF inverter 101-1 to 101-N. Each of the RF inverters 101-1 to 101-N has a respective power input terminal 104-1 to 104-N connected to a positive terminal (+) of a direct current (DC) electrical power supply 103 through an electrical connection 105. Each of the RF inverters 101-1 to 101-N also has a respective ground terminal 108-1 to 108-N connected to a reference ground potential 117 through an electrical connection 107. A negative terminal (−) of the DC power supply 103 is also connected to the reference ground potential 117 through the electrical connection 107. In some embodiments, a controller 121 is connected to direct control of the DC electrical power supply 103 by way of a connection 122.

Each of the RF inverters 101-1 to 101-N also has a respective control signal input terminal 102-1 to 102-N connected to receive a respective control signal from the controller 121 through a respective electrical connection 106-1 to 106-N. The control signals that are received from the controller 121 through the electrical connections 106-1 to 106-N specify how the input signals Vg1 to VgN are to be generated with respect to frequency, magnitude, and phase at a given time. Each of the RF inverters 101-1 to 101-N also has a respective output terminal 112-1 to 112-N through with the respective sinusoidal RF signal Vs1 to VsN is transmitted. Each of the output terminals 112-1 to 112-N is electrically connected through an electrical connection 109 to an input terminal of a capacitor 111. An output terminal of the capacitor 111 is electrically connected to the antenna/electrode 113 through an electrical connection 114. The capacitor 111 functions as a series matching capacitor to facilitate impedance matching with the plasma load 115. The capacitor 111 serves to reduce the difference in phase angle between the voltage and current at the output of the RF power supply system 100. In some embodiments, the capacitor 111 is a variable capacitor that provides for adjustment of its capacitance setting either manually or remotely, such as by way of the controller 121 operating to direct control of a stepper motor that in turn adjusts the capacitance setting of the capacitor 111.

Also, in some embodiments, a voltage/current (V/I) sensor 110 is connected to measure a voltage and a current present on the electrical connection 109 at a location before the input terminal of the capacitor 111, with respect to the RF signal propagation direction that goes from the RF inverters 101-1 to 101-N to the antenna/electrode 113. In some embodiments, the V/I sensor 110 is configured to measure a root-mean-square (RMS) voltage (Vᵣₘₛ), an RMS current (iᵣₘₛ), and a phase angle (φ) between the measured RMS voltage (Vᵣₘₛ) and measured RMS current (iᵣₘₛ) at a given time. In some embodiments, the V/I sensor 110 is also configured to determine an RF power (P) being transmitted through the electrical connection 109 at a given time by using the measured RMS voltage (Vᵣₘₛ), the measured RMS current (iᵣₘₛ), and the phase angle (φ) between the measured RMS voltage (Vᵣₘₛ) and the measured RMS current (iᵣₘₛ) at the given time as follows: P=(Vᵣₘₛ)(iᵣₘₛ)cos(φ). It should be understood that in various embodiments, the V/I sensor 110 can be configured to determine the real-time RF power being transmitted through the electrical connection 109 at any given time using essentially any available electrical measurement or measurement-computation technique. In some embodiments, a signal indicating the RF power (P) determined by the V/I sensor 110 at any given time is conveyed to the controller 121 through an electrical connection 124. Also, in some embodiments, signals indicating the measured RMS voltage (Vᵣₘₛ), the measured RMS current (iᵣₘₛ), and the phase angle (φ) between the measured RMS voltage (Vᵣₘₛ) and measured RMS current (iᵣₘₛ) at any given time are conveyed to the controller 121 through the electrical connection 124.

FIG. 1B shows a schematic view of an RF inverter 101-x, in accordance with some embodiments. The RF inverter 101-x represents an example of each one of the RF inverters 101-1 to 101-N as shown in FIG. 1A. The RF inverter 101-x is electrically connected to receive electrical power from the positive terminal (+) of the DC electrical power supply 103 through the electrical connection 105 at the power input terminal 104-x. The ground terminal 108-x of the RF inverter 101-x is electrically connected to the reference ground potential 117 through the electrical connection 107. The output terminal 112-x of the RF inverter 101-x is electrically connected to the electrical connection 109. In some embodiments, the RF inverter 101-x is connected to receive the input signal Vgx from the controller 121 through the electrical connection 106-x. In some embodiments, the RF inverter 101-x is connected to receive a control signal through the electrical connection 106-x that directs generation of the input signal Vgx onboard the RF inverter 101-x. In some embodiments, the input signal Vgx is a square-waveform (digital waveform) that pulses between a peak positive amplitude and a peak negative amplitude in accordance with a specified cycle frequency, where one cycle corresponds to a duration between adjacent transitions of the input signal Vgx to the peak positive amplitude, and where the specified cycle frequency is a number of cycles per unit time.

The input signal Vgx is transmitted to one or more gates 127 of one or more transistor devices 125. When the input signal Vgx is at the peak positive amplitude a first logic level (such as a high/one) is transmitted to the one or more gates 127 of the one or more transistor devices 125. Conversely, when the input signal Vgx is at the peak negative amplitude a second logic level (such as a low/zero) is transmitted to the one or more gates 127 of the one or more transistor devices 125. In this manner, the input signal Vgx causes the one or more transistor devices 125 to turn on and off in accordance with the frequency of the input signal Vgx. In various embodiments, the frequency of the input signal Vgx can be set at essentially any frequency. Some example frequencies of the input signal Vgx include 400 kiloHertz (kHz), 2 megaHertz (MHz), 13.56 MHz, 27 MHz, 60 MHz, among other frequencies. In some embodiments, a diode 129 is connected between a drain terminal 130 and a source terminal 132 of the one or more transistor devices 125 to limit voltage across the one or more transistor devices 125. When the one or more transistor devices 125 is turned on, voltage across the one or more transistor devices 125 increases until the voltage is limited by the diode 129. The diode 129 functions to protect the one or more transistor devices 125 from excessive electrical current flow.

The RF inverter 101-x includes an inductor 123 that has a first terminal 123A electrically connected to the input terminal 104-x of the RF inverter 101-x. A second terminal 123B of the inductor 123 is electrically connected to the drain terminal 130 of the one or more transistor devices 125. The RF inverter 101-x includes a capacitor 131 that has a first terminal 131A electrically connected to the drain terminal 130 of the one or more transistor devices 125. A second terminal 131B of the capacitor 131 is electrically connected to the source terminal 132 of the one or more transistor devices 125. The RF inverter 101-x also includes a capacitor 133 and an inductor 135 electrically connected in series with the inductor 123. The capacitor 133 has a first terminal 133A electrically connected to the drain terminal 130 of the one or more transistor devices 125. The inductor 135 has a first terminal 135A electrically connected to a second terminal 133B of the capacitor 133. The inductor 135 has a second terminal 135B electrically connected to the output terminal 112-x of the RF inverter 101-x. The RF inverter 101-x includes a capacitor 137 that has a first terminal 137A electrically connected to the output terminal 112-x of the RF inverter 101- x. The capacitor 137 has a second terminal 137B electrically connected to the source terminal 132 of the one or more transistor devices 125. Operation of the one or more transistor devices 125 in accordance with the input signal Vgx as transmitted to the gate(s) 127 of the one or more transistor devices 125, in combination with the inductors 123 and 135 and the capacitors 131, 133, 135, and 137, provides for generation of the sinusoidal output signal Vsx at the output terminal 112-x of the RF inverter 101-x. The amplitude of the sinusoidal output signal Vsx at the output terminal 112-x is controlled by the controlling the voltage level at the input terminal 104-x of the RF inverter 101-x. The frequency and phase of the sinusoidal output signal Vsx at the output terminal 112-x is controlled by controlling the frequency and phase of the input signal Vgx.

In some embodiments, the one or more transistor devices 125 is a field effect transistor (FET). In some embodiments, such as described above with regard to FIG. 1B, the one or more transistor devices 125 is an n-type FET that turns on when at least a threshold voltage is applied to the gate 127. However, in other embodiments, the one or more transistor devices 125 is a p-type FET that turns off when at least a threshold voltage is applied to the gate 127. In some embodiments, the one or more transistor devices 125 is implemented as a metal oxide semiconductor field effect transistor (MOSFET). In some embodiments, the one or more transistor devices 125 is implemented as an insulated gate bipolar transistor (IGBT), or a metal semiconductor field effect transistor (MESFET), or a junction field effect transistor (JFET), among others. In some embodiments, the one or more transistor devices 125 is made from silicon carbide, or silicon, or gallium nitride. In some embodiments, the one or more transistor devices 125 is connected in a half-bridge configuration. In some embodiments, the one or more transistor devices 125 is connected in a full-bridge configuration. In some embodiments, the RF inverter 101-x is configured to have a single-switch inverter topology in which the multiple transistor devices 125 are connected in parallel and driven simultaneously. In some embodiments, the input signal Vgx is duplicated and/or split into multiple gate driving signals that drive multiple transistor devices 125.

FIG. 1C shows various ways in which the RF inverters 101-1 to 101-N can be controlled at a given time by way of the input signals Vg1 to VgN, in accordance with some embodiments. The RF inverter 1 101-1 receives the input signal Vg1 as a cycling square-waveform signal having a specified frequency (f). The RF inverter 2 101-2 receives the input signal Vg2 as the cycling square-waveform signal having the specified frequency (f) and a specified phase-shift 201 relative to the input signal Vg1. The input signal VgN that is received by the RF inverter N 101-N is defined so that the RF inverter N 101-N is turned OFF, i.e., so that the output signal VsN is not generated. In some embodiments, when the one or more transistor devices 125 of the RF inverter 101-x is configured as an n-type FET, the input signal Vgx is provided as essentially a zero voltage signal when the RF inverter 101-x is to be turned OFF. In some embodiments, the specified frequency (f) of the various input signals Vg1 to VgN that are ON at a given time is substantially the same frequency (f). However, in some embodiments, any one or more of the various input signals Vg1 to VgN that are ON at a given time can be defined to have a different frequency (f) than others of the input signals Vg1 to VgN that are ON at the given time. By controlling the various input signals Vg1 to VgN, each RF inverter 101-x can be separately/independently controlled to be ON or OFF at a given time. Also, by controlling the various input signals Vg1 to VgN, any RF inverter 101-x that is ON at a given time can be controlled to generate a phase-shifted output signal Vsx relative to one or more others of the RF inverters 101-1 to 101-N that are also ON at the given time. In some embodiments, each RF inverter 101-x that is to generate a phase-shifted output signal Vsx at a given time has its input signal Vgx phase-shifted by a substantially same amount. However, in some embodiments, different ones of the input signals Vs1 to VsN can be phase-shifted by different amounts at a given time.

FIG. 1D shows an example vertical cross-section diagram of a plasma processing system 161, in accordance with some embodiments of the present disclosure. The plasma processing system 161 is an inductively coupled system in which RF power is transmitted from the antenna 113 into the chamber 116. The chamber 116 is electrically connected to a reference ground potential 119. A plasma processing region 163 is provided within the chamber 116, and a substrate support structure 173 is disposed within the chamber 116 to hold a substrate 165 in exposure to the plasma processing region 163 during plasma processing operations. A plasma 115A (represented by the dashed oval region) is generated within the plasma processing region 163 to affect a change to the substrate 165 in a controlled manner. In various fabrication processes, the change to the substrate 165 can be a change in material or surface condition on the substrate 165. For example, in various fabrication processes, the change to the substrate 165 can include one or more of etching of a material from the substrate 165, deposition of a material on the substrate 165, or modification of material present on the substrate 165. It should be understood that the plasma processing system 161 can be any type of plasma processing system in which RF power is transmitted from the antenna 113 disposed outside the chamber 116 to a process gas within the chamber 116 to generate the plasma 115A within the plasma processing region 163. An upper window structure 167 is provided to allow for transmission of RF power from the antenna 113 through the upper window structure 167 and into the plasma processing region 163 of the chamber 116.

In some embodiments, the substrate 165 is a semiconductor wafer undergoing a fabrication procedure. However, it should be understood that in various embodiments, the substrate 165 can be essentially any type of substrate that is subjected to a plasma-based fabrication process. For example, in some embodiments, the substrate 165 as referred to herein can be a substrate formed of silicon, sapphire, GaN, GaAs or SiC, or other substrate materials, and can include glass panels/substrates, metal foils, metal sheets, polymer materials, or the like. Also, in various embodiments, the substrate 165 referred to herein may vary in form, shape, and/or size. For example, in some embodiments, the substrate 165 referred to herein may correspond to a 200 mm (millimeters) diameter semiconductor wafer, a 300 mm diameter semiconductor wafer, or a 450 mm diameter semiconductor wafer, among other semiconductor wafer sizes. Also, in some embodiments, the substrate 165 referred to herein may correspond to a non-circular substrate, such as a rectangular substrate for a flat panel display, or the like, among other shapes.

The plasma processing region 163 within the chamber 116 is connected to a process gas supply system 169, such that one or more process gas(es) can be supplied in a controlled manner to the plasma processing region 163, as represented by arrow 171. The process gas supply system 169 includes one or more process gas sources and an arrangement of valves and mass flow controllers to enable provision of the one or more process gas(es) to the plasma processing region 163 with a controlled flow rate and with a controlled flow time. Also, in various embodiments, the one or more process gas(es) are delivered to the plasma processing region 163 in both a temporally controlled manner and a spatially controlled manner relative to the substrate 165. The ICP processing system 161 operates by having the process gas supply system 169 flow one or more process gases into the plasma processing region 163, and by applying RF power from the antenna 113 to the one or more process gases to transform the one or more process gases into the plasma 115A in exposure to the substrate 165, in order to cause a change in material or surface condition on the substrate 165. In some embodiments, the controller 121 is connected to control operation of the process gas supply system 169.

The antenna 113 is disposed above the upper window structure 167. In the example of FIG. 1D, the antenna 113 is formed as a radial coil assembly, with the shaded parts of the antenna 113 turning into the page of the drawing and with the unshaded parts of the antenna 113 turning out of the page of the drawing. FIG. 1E shows a top view of the antenna 113, in accordance with some embodiments. In various embodiments, the antenna 113 can have essentially any configuration that is suitable for transmitting RF power through the upper window structure 167 and into the plasma processing region 163. In various embodiments, the antenna 113 can have any number of turns and any cross-section size and shape (circular, oval, rectangular, trapezoidal, etc.) as appropriate to provide for transmission of RF power through the upper window structure 167 into the plasma processing region 163. The antenna 113 is electrically connected to RF power supply system 100 through the electrical connection 114.

FIG. 1F shows a diagram of the controller 121, in accordance with some example embodiments. The controller 121 includes a processor 149, a storage hardware unit (HU) 151 (e.g., memory), an input HU 141, an output HU 145, an input/output (I/O) interface 143, an I/O interface 147, a network interface controller (NIC) 155, and a data communication bus 153. The processor 149, the storage HU 151, the input HU 141, the output HU 145, the I/O interface 143, the I/O interface 147, and the NIC 155 are in data communication with each other by way of the data communication bus 153. Examples of the input HU 141 include a mouse, a keyboard, a stylus, a data acquisition system, a data acquisition card, etc. Examples of the output HU 145 include a display, a speaker, a device controller, etc. Examples of the NIC 155 include a network interface card, a network adapter, etc. In various embodiments, the NIC 155 is configured to operate in accordance with one or more communication protocols and associated physical layers, such as Ethernet and/or EtherCAT, among others. Each of the I/O interfaces 143 and 147 is defined to provide compatibility between different hardware units coupled to the I/O interface. For example, the I/O interface 143 can be defined to convert a signal received from the input HU 141 into a form, amplitude, and/or speed compatible with the data communication bus 153. Also, the I/O interface 147 can be defined to convert a signal received from the data communication bus 153 into a form, amplitude, and/or speed compatible with the output HU 145. Although various operations described herein are performed by the processor 149 of the controller 121, it should be understood that in some embodiments various operations can be performed by multiple processors of the controller 121 and/or by multiple processors of multiple computing systems connected to the controller 121.

In various embodiments, the plasma processing system 161 is integrated with electronics for controlling its operation before, during, and after processing of the substrate 165, where the electronics are implemented within the controller 121 that is configured and connected to control various components and/or sub-parts of the plasma processing system 161. Depending on substrate 165 processing requirements and/or the particular configuration of the plasma processing system 161, the controller 121 is programmed to control any process and/or component disclosed herein, including delivery of process gas(es) by the process gas supply system 169, temperature settings (e.g., heating and/or cooling), pressure settings, vacuum settings, power settings, RF power supply system 100 settings, electrical signal frequency settings, gas flow rate settings, fluid delivery settings, positional and operation settings, substrate 165 transfers into and out of the chamber 116 and/or into and out of load locks connected to or interfaced with the plasma processing system 161, among others.

Broadly speaking, in a variety of embodiments, the controller 121 is defined as electronics having various integrated circuits, logic, memory, and/or software that direct and control various tasks/operations, such as receiving instructions, issuing instructions, controlling device operations, enabling cleaning operations, enabling endpoint measurements, enabling metrology measurements (optical, thermal, electrical, etc.), among other tasks/operations. In some embodiments, the integrated circuits within the controller 121 include one or more of firmware that stores program instructions, a digital signal processor (DSP), an Application Specific Integrated Circuit (ASIC) chip, a programmable logic device (PLD), one or more microprocessors, and/or one or more microcontrollers that execute program instructions (e.g., software), among other computing devices. In some embodiments, the program instructions are communicated to the controller 121 in the form of various individual settings (or program files), defining operational parameters for carrying out a process on the substrate 165 within the plasma processing system 161. In some embodiments, the operational parameters are included in a recipe defined by process engineers to accomplish one or more processing steps during the fabrication of one or more layers, materials, metals, oxides, silicon, silicon dioxide, surfaces, circuits, and/or dies on the substrate 165.

In some embodiments, the controller 121 is a part of, or connected to, a computer that is integrated with, or connected to, the plasma processing system 161, or that is otherwise networked to the plasma processing system 161, or a combination thereof. For example, in some embodiments, the controller 121 is implemented in a “cloud” or all or a part of a fab host computer system, which allows for remote access for control of substrate 165 processing by the plasma processing system 161. The controller 121 enables remote access to the plasma processing system 161 to provide for monitoring of current progress of fabrication operations, provide for examination of a history of past fabrication operations, provide for examination of trends or performance metrics from a plurality of fabrication operations, provide for changing of processing parameters, provide for setting of subsequent processing steps, provide for specification of RF power supply system 100 operational parameters, and/or provide for initiation of a new substrate 165 fabrication process.

In some embodiments, a remote computer, such as a server computer system, provides process recipes to the controller 121 over a computer network, which includes a local network and/or the Internet. The remote computer includes a user interface that enables entry or programming of parameters and/or settings, which are then communicated to the controller 121 from the remote computer. In some examples, the controller 121 receives instructions in the form of settings for processing the substrate 165 within the plasma processing system 161. It should be understood that the settings are specific to a type of process to be performed on the substrate 165 and a type of tool/device/component that the controller 121 interfaces with or controls. In some embodiments, the controller 121 is distributed, such as by including one or more discrete controller(s) 121 that are networked together and synchronized to work toward a common purpose, such as operating the plasma processing system 161 to perform a prescribed process on the substrate 165. An example of a distributed controller 121 for such purposes includes one or more integrated circuits on a chamber in communication with one or more integrated circuits located remotely (such as at a platform level or as part of a remote computer) that combine to control a process in the chamber. Also, depending on a process operation to be performed by the plasma processing system 161, the controller 121 communicates with various entities through a semiconductor manufacturing factory, such as with one or more of other tool circuits or modules, other tool components, cluster tools, other tool interfaces, adjacent tools, neighboring tools, distributed tools, a main computer, another controller, or tools used in material transport that bring containers of substrates 165 to and from tool locations and/or load ports in the semiconductor manufacturing factory.

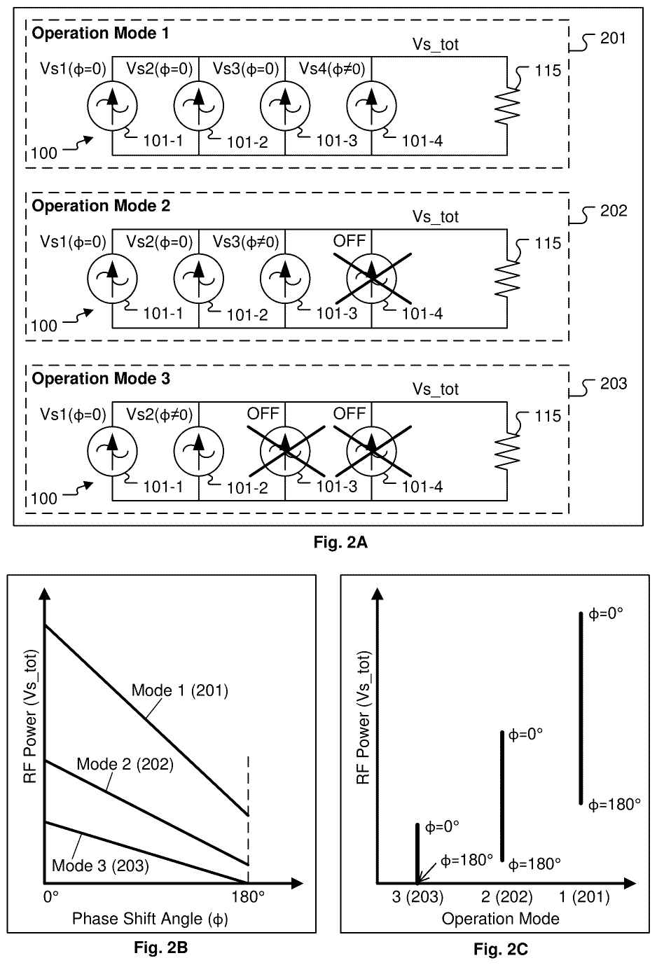

FIG. 2A shows an example of how the RF power supply system 100 can be operated in accordance with multiple operation modes, in accordance with some embodiments. In the example of FIG. 2A, the RF power supply system 100 includes four RF inverters 101-1 to 101-4 connected to supply RF power (represented by Vs_tot) to the plasma load 115. When operating (ON), each RF inverter 101-1 to 101-4 is configured to generate a respective sinusoidal RF signal Vs1 to Vs4, respectively. The RF signals Vs1, Vs2, Vs3, and/or Vs4 generated by the RF inverters 101-1 to 101-4 that are operating (ON) combine to form the output RF signal Vs_tot that is transmitted to the plasma load 115. In a given operation mode of the RF power supply system 100, one or more of the RF inverters 101-1 to 101-N is/are operating (ON) in-phase with each other at a reference phase (φ=0), and one or more of the RF inverters 101-1 to 101-N is/are operating out of phase (φ≠0) (outphased) relative to the reference phase (φ=0), and zero or more of the RF inverters 101-1 to 101-N is/are not operating (OFF). The input signals Vg1 to VgN applied to the RF inverters 101-1 to 101-N, respectively, are used to define the reference phase (φ=0) and the amount of outphasing (φ≠0). In a first operation mode 201 in the example of FIG. 2A, each of the RF inverters 101-1, 101-2, 101-3, and 101-4 is operating (ON), with the RF inverters 101-1, 101-2, and 101-3 operating in-phase with each other at a reference phase (φ=0), and with the RF inverter 101-4 operating outphased (φ≠0) relative to the reference phase (φ=0). In a second operation mode 202 in the example of FIG. 2A, each of the RF inverters 101-1, 101-2, and 101-3 is operating (ON), with the RF inverters 101-1 and 101-2 operating in-phase with each other at a reference phase (φ=0), and with the RF inverter 101-3 operating outphased (φ≠0) relative to the reference phase (φ=0). In the second operation mode 202, the RF inverter 101-4 is not operating (OFF). In a third operation mode 203 in the example of FIG. 2A, each of the RF inverters 101-1 and 101-2 is operating (ON), with the RF inverter 101-1 operating at a reference phase (φ=0), and with the RF inverter 101-2 operating outphased (φ≠0) relative to the reference phase (φ=0). In the third operation mode 203, each of the RF inverters 101-3 and 101-4 is not operating (OFF).

FIG. 2B shows plots of the output RF power provided by the output RF signal Vs_tot for the three operational modes 201, 202, and 203, as a function of the phase shift angle (φ≠0) applied to the outphased ones of the RF inverters 101-1 to 101-N, in accordance with some embodiments. The phase shift angle (φ≠0) extends over a range from zero degree to 180 degrees, where zero degrees corresponds to no outphasing applied and 180 degrees corresponds to maximum outphasing applied to the outphased ones of the RF inverters 101-1 to 101-N. The first operation mode 201 has the highest average magnitude of the output RF power and the largest gradient of output RF power as a function of phase shift angle (φ). The third operation mode 203 has the lowest magnitude of the output RF power and the smallest gradient of output RF power as a function of phase shift angle (φ). The median magnitude of the output RF power of the second operation mode 202 is less than the median magnitude of the output RF power of the first operation mode 201. Also, the median magnitude of the output RF power of the second operation mode 202 is greater than the median magnitude of the output RF power of the third operation mode 203. Similarly, the gradient of output RF power as a function of phase shift angle (φ) of the second operation mode 202 is between that of the first operation mode 201 and the third operation mode 203. FIG. 2B shows that as the number of operating (ON) ones of the RF inverters 101-1 to 101-N decreases, while maintaining the same number of operating (ON) and outphased ones of the RF inverters 101-1 to 101-N, both the median magnitude of the available output RF power range and the gradient of output RF power as a function of phase shift angle (φ) decreases. Conversely, FIG. 2B shows that as the number of operating (ON) ones of the RF inverters 101-1 to 101-N increases, while maintaining the same number of operating (ON) and outphased ones of the RF inverters 101-1 to 101-N, both the median magnitude of the available output RF power range and the gradient of output RF power as a function of phase shift angle (φ) increases.

FIG. 2C shows plots of the output RF power provided by the output RF signal Vs_tot for the three operational modes 201, 202, and 203, in accordance with some embodiments. FIG. 2C shows that in some embodiments there is overlap in the available output RF power ranges for neighboring operation modes. For example, FIG. 2C shows that at a phase shift angle (φ) near zero for the outphased ones of the RF inverters 101-1 to 101-N in the second operation mode 202, the output RF power for the second operation mode 202 overlaps the output RF power for the first operation mode 201, where this output RF power overlap exists over a portion (less than all) of the available phase shift angle (φ) range for the outphased ones of the RF inverters 101-1 to 101-N in the second operation mode 202. Similarly, at a phase shift angle (φ) near zero for the outphased ones of the RF inverters 101-1 to 101-N in the third operation mode 203, the output RF power for third operation mode 203 overlaps the output RF power for the second operation mode 202, where this output RF power overlap exists over a portion (less than all) of the available phase shift angle (φ) range for the outphased ones of the RF inverters 101-1 to 101-N in the third operation mode 203. Therefore, in some embodiments, it is possible to have a same output RF power in multiple different operating modes of the RF power supply system 100. In some embodiments, the RF power supply system 100 is operated to transition from one operation mode to another operation mode, and so on, in order to have an overall output RF power range for the RF power supply system 100 that is greater than an output RF power range for an individual operation mode of the RF power supply system 100.

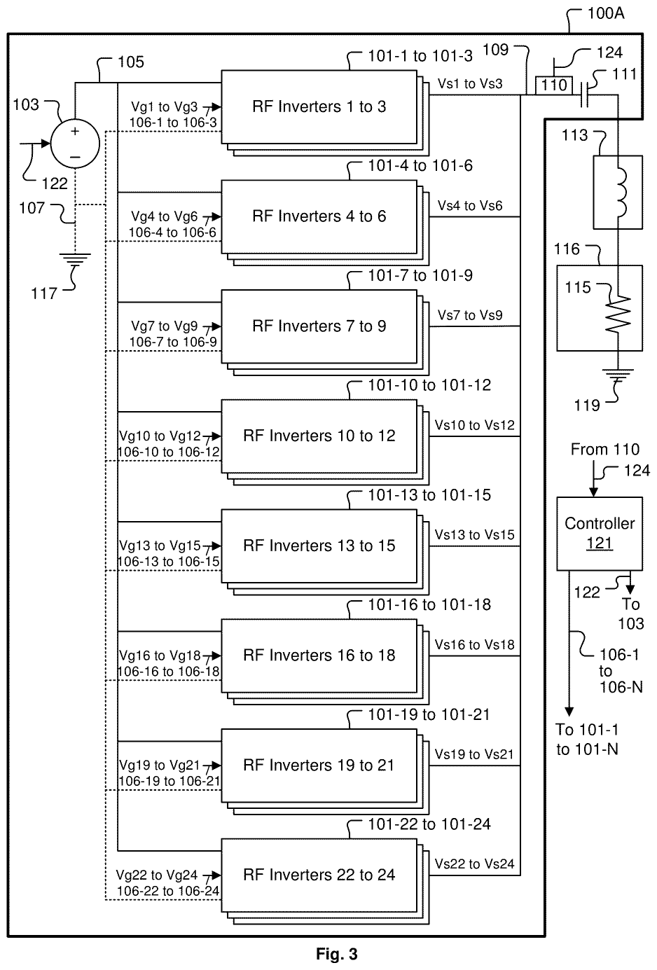

FIG. 3 shows an example RF power supply system 100A corresponding to a particular implementation of the RF power supply system 100, in accordance with some embodiments. There are 24(N=24 ) RF inverters 101-1 to 101-24 in the example RF power supply system 100A. The RF inverters 101-1 to 101-24 are organized into groupings of three for operation mode control purposes. Specifically, RF inverters 101-1 to 101-3 are in a first control grouping. RF inverters 101-4 to 101-6 are in a second control grouping. RF inverters 101-7 to 101-9 are in a third control grouping. RF inverters 101-10 to 101-12 are in a fourth control grouping. RF inverters 101-13 to 101-15 are in a fifth control grouping. RF inverters 101-16 to 101-18 are in a sixth control grouping. RF inverters 101-19 to 101-21 are in a seventh control grouping. RF inverters 101-22 to 101-24 are in an eighth control grouping. Each of the first, second, third, fourth, fifth, sixth, seventh, and eighth control groupings is independently controllable with respect to being operational (ON/OFF) and with respect to the applied phase shift angle (φ) for outphasing. In various embodiments, the controller 121 is programmed to control which of the first, second, third, fourth, fifth, sixth, seventh, and eighth control groupings of the RF inverters 101-1 to 101-24 is operational (ON) at a given, not operational (OFF) at the given time, and outphased by an applied phase shift angle (φ) at the given time. In some embodiments, the phase shift angle (φ) is applied to the ones of the input signals Vg1 to Vg24 that are phase-shifted (outphased) at the given time, with the phase shift angle (φ) being defined relative to the phase of the ones of the input signals Vg1 to Vg24 that are not phase-shifted (not outphased) at the given time.

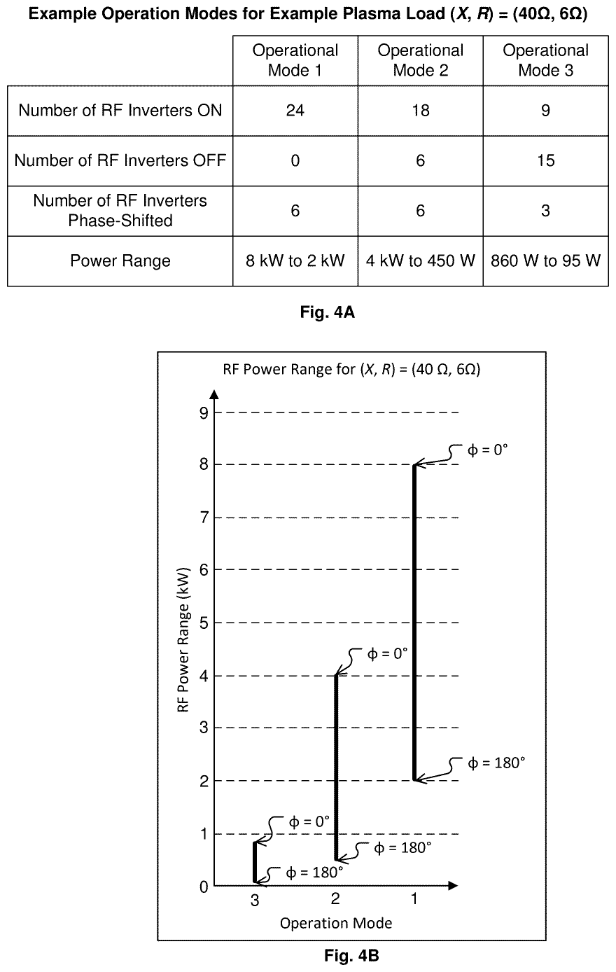

FIG. 4A shows a table of example operational modes for the example RF power supply system 100A of FIG. 3, in accordance with some embodiments. It should be understood that the example operation modes shown in FIG. 4A are provided to facilitate description of how operation modes are defined for the example RF power supply system 100/100A and are in no way intended to represent an exhaustive set of possible operation modes which may be defined for operation of the example RF power supply system 100/100A. The example operation modes shown in FIG. 4A correspond to an example plasma load 115 defined by a reactance of 40 Ohms and resistance of 6 Ohms. FIG. 4A shows an example operation mode 1 in which 24 of the RF inverters 101-1 to 101-24 are operational (ON) at a given time, and in which zero of the RF inverters 101-1 to 101-24 are not operational (OFF) at the given time, and in which 6 of the RF inverters 101-1 to 101-24 that are operational (ON) at the given time are also outphased by the phase shift angle (φ) at the given time relative to others of the RF inverters 101-1 to 101-24 that are operational (ON) at the given time. FIG. 4A also shows an example operation mode 2 in which 18 of the RF inverters 101-1 to 101-24 are operational (ON) at a given time, and in which 6 of the RF inverters 101-1 to 101-24 are not operational (OFF) at the given time, and in which 6 of the RF inverters 101-1 to 101-24 that are operational (ON) at the given time are also outphased by the phase shift angle (φ) at the given time relative to others of the RF inverters 101-1 to 101-24 that are operational (ON) at the given time. FIG. 4A also shows an example operation mode 3 in which 9 of the RF inverters 101-1 to 101-24 are operational (ON) at a given time, and in which 15 of the RF inverters 101-1 to 101-24 are not operational (OFF) at the given time, and in which 3 of the RF inverters 101-1 to 101-24 that are operational (ON) at the given time are also outphased by the phase shift angle (φ) at the given time relative to others of the RF inverters 101-1 to 101-24 that are operational (ON) at the given time. It should be understood that in other operational modes, any one or more of the RF inverters 101-1 to 101-24 can be operational (ON) at a given time, with a balance of the RF inverters 101-1 to 101-24 not being operational (OFF) at the given time, and in with some of the RF inverters 101-1 to 101-24 that are operational (ON) at the given time also being outphased by the phase shift angle (φ) at the given time relative to others of the RF inverters 101-1 to 101-24 that are operational (ON) at the given time.

FIG. 4B shows plots of the output RF power provided by the output RF signal Vs_tot for the operational modes 1, 2, and 3 of FIG. 4A for the example RF power supply system 100/100A, in accordance with some embodiments. The output RF power range for operation mode 1 extends from about 8 kW to about 2 kW. The output RF power range for operation mode 2 extends from about 4 kW to about 450 W. The output RF power range for operation mode 3 extends from about 860 W to about 95 W. FIG. 4B shows that over some range of phase shift angle (φ) there is overlap in the output RF power for operation modes 1 and 2 of the example RF power supply system 100/100A. Similarly, over some range of phase shift angle (φ) there is overlap in the output RF power for operation modes 2 and 3 of the example RF power supply system 100/100A. Therefore, in some embodiments, it is possible to control the RF power supply system 100/100A to generate the same output RF power in different operation modes through control of the phase shift angle (φ) applied in each of the different operation modes.

In some embodiments, a target RF power setpoint (RFsp) is specified for a plasma processing operation to be performed by the plasma processing system 161. In some embodiments, the controller 121 operates to determine an operation mode for the RF power supply system 100/100A that will provide an output RF power range that includes the target RF power setpoint (RFsp). In some embodiments, the controller 121 accesses a database or lookup table that includes output RF power range data for various operation modes of the RF power supply system 100/100A in supplying RF power to the plasma load 115 characterized as having a particular impedance (X, R, where X is the reactance and R is the resistance).

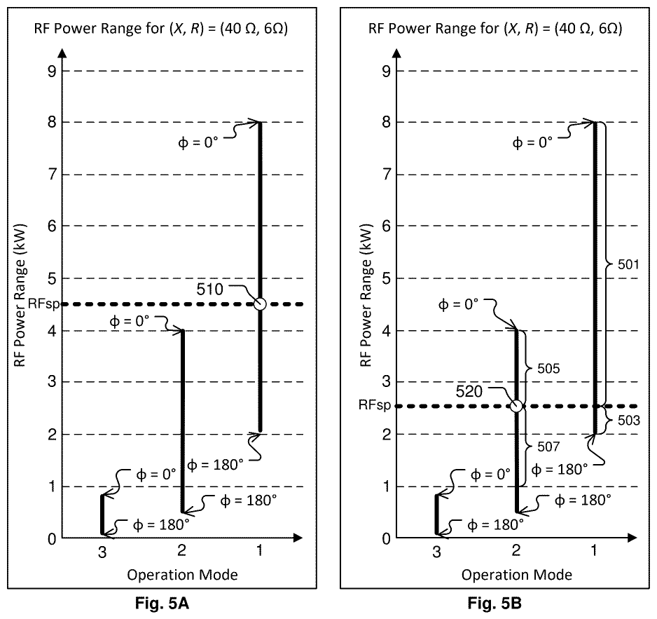

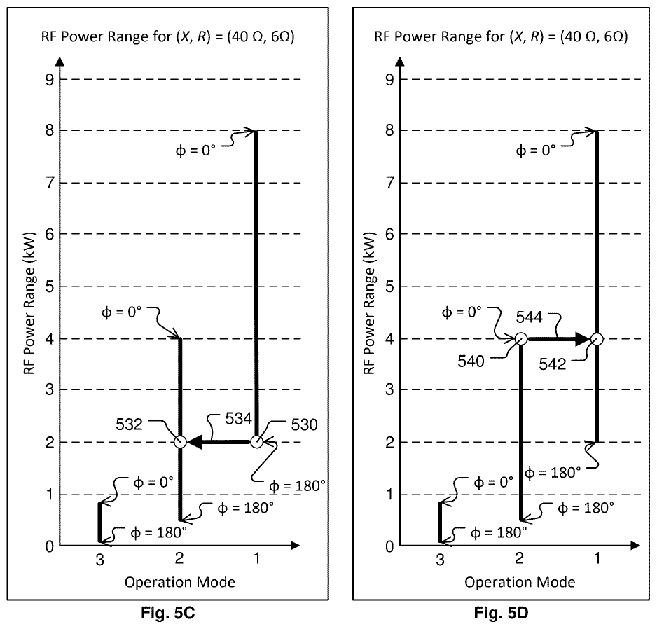

FIG. 5A shows an example situation in which the target RF power setpoint (RFsp) falls within one of multiple operation modes of the RF power supply system 100/100A, in accordance with some embodiments. When there is just one operation mode of the RF power supply system 100/100A capable of providing the target RF power setpoint (RFsp), the controller 121 directs the RF power supply system 100/100A to operate in accordance with that one operation mode. For example, in FIG. 5A, because the target RF power setpoint (RFsp) of 4.5 kW can be provided by operation mode 1, but not operation modes 2 and 3, the controller 121 directs the RF power supply system 100/100A to operate in accordance with operation mode 1 to generate RF power at the target RF power setpoint (RFsp), as indicated by the operation mode setting 510.

FIG. 5B shows an example situation in which the target RF power setpoint (RFsp) can be achieved by multiple operation modes of the RF power supply system 100/100A, in accordance with some embodiments. In some embodiments, when there are multiple operation modes of the RF power supply system 100/100A capable of providing the target RF power setpoint (RFsp), the controller 121 directs the RF power supply system 100/100A to operate in accordance with the operation mode that does not have the smallest output RF power adjustability as a function of phase shift angle (φ) in either phase shift angle (φ) adjustment direction (either decreasing toward zero degree or increasing toward 180 degrees). For example, in FIG. 5B, the target RF power setpoint (RFsp) of 2.5 kW can be provided by both operation mode 1 with a phase shift angle (φ) of about 165 degrees and operation mode 2 with a phase shift angle (φ) of about 80 degrees. Operation mode 1 has an upward output RF power adjustability range 501 in the descending direction of phase shift angle (φ) adjustment (from about 165 degrees to zero degree). Operation mode 1 also has a downward output RF power adjustability range 503 in the ascending direction of phase shift angle (φ) adjustment (from about 165 degrees to about 180 degrees). Operation mode 2 has an upward output RF power adjustability range 505 in the descending direction of phase shift angle (φ) adjustment (from about 80 degrees to zero degree). Operation mode 2 has a downward output RF power adjustability range 507 in the ascending direction of phase shift angle (φ) adjustment (from about 80 degrees to about 180 degrees). In some embodiments, because the downward output RF power adjustability range 503 of operation mode 1 is the smallest output RF power adjustability range as a function of phase shift angle (φ) in either phase shift angle (φ) adjustment direction from the target RF power setpoint (RFsp) for operation modes 1 and 2, the controller 121 determines that operation mode 2 is to be used for operation of the RF power supply system 100/100A to generate RF power at the target RF power setpoint (RFsp), as indicated by the operation mode setting 520.

During operation of the plasma processing system 161, the output RF power of the RF power supply system 100/100A can change as other operating parameters change, such as temperature. For example, in some embodiments, the output RF power of the RF power supply system 100/100A will drift upward with increasing temperature and downward with decreasing temperature. The controller 121 is programmed to automatically adjust the phase shift angle (φ) of the outphased ones of the RF inverters 101-1 to 101-N to maintain the output RF power at the target RF power setpoint (RFsp). For example, in some embodiments, the controller 121 increases the phase shift angle (φ) of the outphased ones of the RF inverters 101-1 to 101-N as the temperature of the RF power supply system 100/100A increases to maintain the output RF power at the target RF power setpoint (RFsp). Then, when the phase shift angle (φ) of the outphased ones of the RF inverters 101-1 to 101-N reaches about 180 degrees (or gets within a specified range of 180 degrees, e.g., within about 5 degrees of 180 degrees) in a current operation mode, the controller 121 operates to shift the RF power supply system 100/100A into another operation mode that provides for maintaining the output RF power at the target RF power setpoint (RFsp).

FIG. 5C shows an example of the controller 121 operating to shift the RF power supply system 100/100A from operation mode 1 to operation mode 2 as the output RF power of the RF power supply system 100/100A drifts upward with increasing temperature, in accordance with some embodiments. With the RF power supply system 100/100A operating in operation mode 1, the phase shift angle (φ) of the outphased ones of the RF inverters 101-1 to 101-N is automatically increased by the controller 121 as needed to maintain the output RF power at the target RF power setpoint (RFsp) until the phase shift angle (φ) is about 180 degrees and cannot be adjusted further, as indicated by the operation mode setting 530. Then, the controller 121 operates to automatically shift the RF power supply system 100/100A from operation mode 1 to operation mode 2, as indicated by the arrow 534 and the operation mode setting 532. The controller 121 then continues to adjust the phase shift angle (φ) of the outphased ones of the RF inverters 101-1 to 101-N in operation mode 2 as needed to maintain the output RF power of the RF power supply system 100/100A at the target RF power setpoint (RFsp).

FIG. 5D shows an example of the controller 121 operating to shift the RF power supply system 100/100A from operation mode 2 to operation mode 1 as the output RF power of the RF power supply system 100/100A drifts downward with decreasing temperature, in accordance with some embodiments. With the RF power supply system 100/100A operating in operation mode 2, the phase shift angle (φ) of the outphased ones of the RF inverters 101-1 to 101-N is automatically decreased by the controller 121 as needed to maintain the output RF power at the target RF power setpoint (RFsp) until the phase shift angle (φ) is about 0 degrees and cannot be adjusted further, as indicated by the operation mode setting 540. Then, the controller 121 operates to automatically shift the RF power supply system 100/100A from operation mode 2 to operation mode 1, as indicated by the arrow 544 and the operation mode setting 542. The controller 121 then continues to adjust the phase shift angle (φ) of the outphased ones of the RF inverters 101-1 to 101-N in operation mode 1 as needed to maintain the output RF power of the RF power supply system 100/100A at the target RF power setpoint (RFsp). Again, it should be understood that the controller 121 operates to automatically shift the RF power supply system 100/100A between any two or more viable operation modes as needed to maintain the output of RF power of the RF power supply system 100/100A at the target RF power setpoint (RFsp).

The output RF power range for a given operation mode of the RF power supply system 100/100A changes as a function of the impedance of the plasma load 115. For this reason, in some embodiments, the database (lookup table) that is used by the controller 121 to determine the appropriate operation mode of the RF power supply system 100/100A for the target RF power setpoint (RFsp) includes output RF power range data for the different viable operation modes as a function of the impedance of the plasma load 115. Therefore, with information available on impedance of the plasma load 115 for a given plasma processing operation, the controller 121 operates to determine an appropriate operation mode of the RF power supply system 100/100A for the target RF power setpoint (RFsp) with consideration of the impedance of the plasma load 115. In some embodiments, the impedance of the plasma load 115 is determined in real-time and is provided to the controller 121 as an input parameter.

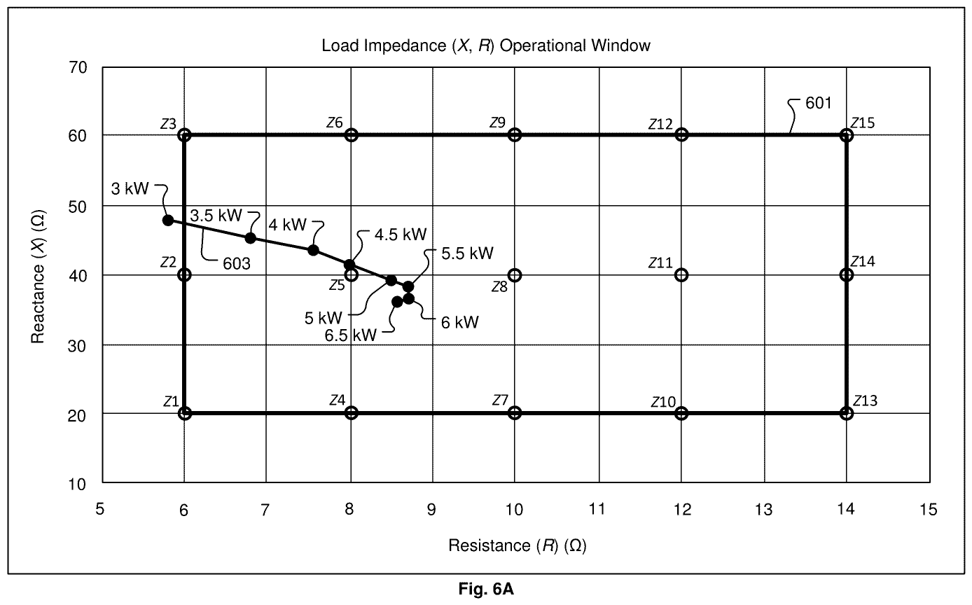

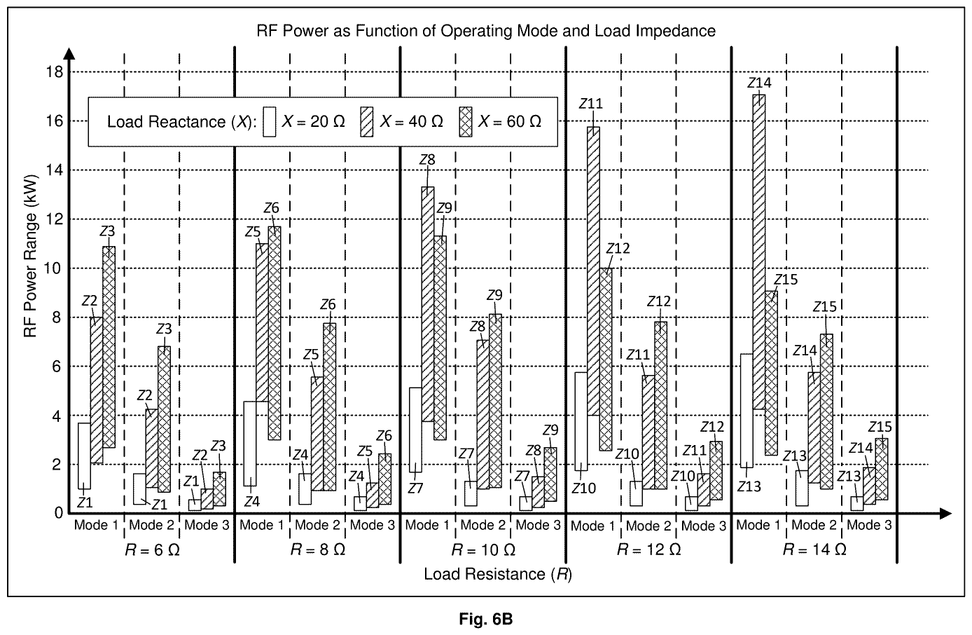

FIG. 6A shows a chart that displays an example plasma load 115 impedance (X, R) operational window 601, in accordance with some embodiments. In some embodiments, it is desirable to operate the RF power supply system 100/100A to drive the plasma load 115 at any impedance within the operational window 601. FIG. 6A includes an example curve 603 that indicates how the output RF power of the RF power supply system 100/100A can move with changes in the impedance (X, R) of the plasma load 115. In some embodiments, the database (lookup table) that is used by the controller 121 to determine the appropriate operation mode of the RF power supply system 100/100A for the target RF power setpoint (RFsp) includes output RF power range data for the different viable operation modes at each of multiple impedance points Z1 to Z15, by way of example, within the plasma load 115 impedance (X, R) operational window 601.

FIG. 6B shows an example chart that illustrates the output RF power ranges for different viable operation modes (operation modes 1, 2, and 3) at each of the multiple impedance points Z1 to Z15 within the plasma load 115 impedance (X, R) operational window 601 of FIG. 6A, in accordance with some embodiments. The chart shown in FIG. 6B is a graphical representation of the data stored in the database (lookup table) that is used by the controller 121 to determine the appropriate operation mode of the RF power supply system 100/100A for the target RF power setpoint (RFsp) and specified plasma load 115 impedance (X, R). In some embodiments, the controller 121 is programmed to interpolate between the output RF power range data for the different viable operation modes at each of multiple impedance points Z1 to Z15 in order to determine the appropriate operation mode of the RF power supply system 100/100A for the target RF power setpoint (RFsp) and extant plasma load 115 impedance (X, R).

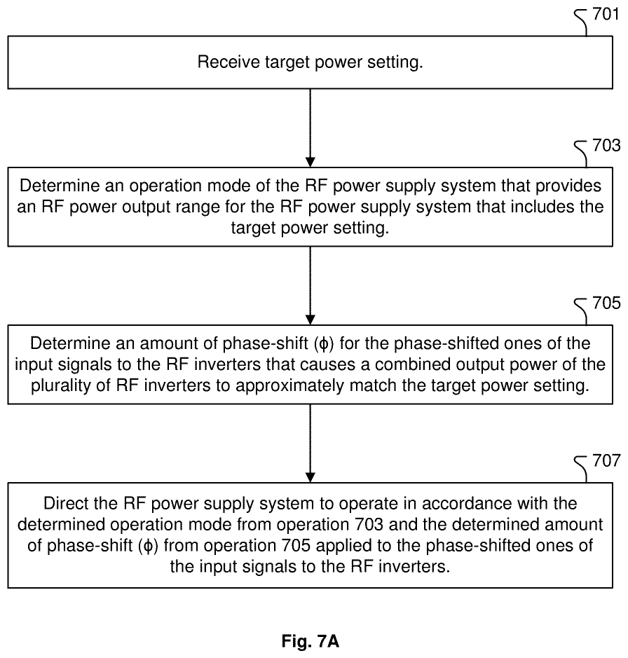

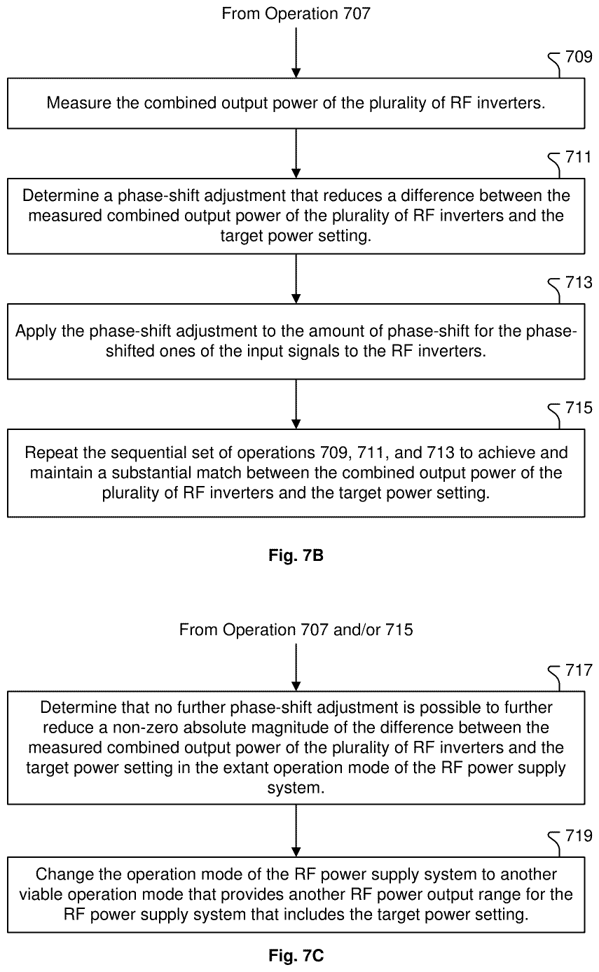

FIG. 7A shows a flowchart of a method for operating an RF power supply system (e.g., 100/100A), in accordance with some embodiments. The method includes an operation 701 for receiving a target RF power setpoint (RFsp). From the operation 701, the method proceeds with an operation 703 for determining an operation mode of the RF power supply system (e.g., 100/100A) that provides an RF power output range for the RF power supply system (e.g., 100/100A) that includes the target RF power setpoint (RFsp). The RF power supply system (e.g., 100/100A) includes a plurality of RF inverters (e.g., 101-1 to 101-N). Each of the plurality of RF inverters (e.g., 101-1 to 101-N) is configured to generate a respective sinusoidal RF signal (e.g., Vs1 to VsN) from a respective input signal (e.g., Vg1 to VgN) applied to one or more gates (e.g., 127) of one or more respective transistor devices (e.g., 125). The operation mode determined in the operation 703 is defined by which of the plurality of RF inverters (e.g., 101-1 to 101-N) are on at a given time, which of the plurality of RF inverters (e.g., 101-1 to 101-N) are off at the given time, and which of the plurality of RF inverters (e.g., 101-1 to 101-N) are operated in accordance with phase-shifted ones of the input signals (e.g., Vg1 to VgN) at the given time.

The operation mode determined in operation 703 is one of multiple viable operation modes of the RF power supply system (e.g., 100/100A). Each of the multiple viable operation modes provides a respective RF power output range for the RF power supply system (e.g., 100/100A) that includes the target RF power setpoint (RFsp). Also, as described with regard to FIG. 5B, the operation mode determined in operation 703 also provides for a larger adjustability range in the combined output power of the plurality of RF inverters (e.g., 101-1 to 101-N) from the target RF power setpoint (RFsp) as compared to others of the multiple viable operation modes. The operation mode determined in operation 703 is also dependent upon an impedance of a load (e.g., plasma load 115) to which the RF power supply system (e.g., 100/100A) is delivering RF power. In some situations, the operation mode determined in operation 703 includes multiple ones of the plurality of RF inverters (e.g., 101-1 to 101-N) operating in accordance with a non-phase-shifted input signal (e.g., Vg1(φ=0) to VgN(φ=0)) at a given time and multiple ones of the plurality of RF inverters (e.g., 101-1 to 101-N) operating in accordance with the phase-shifted ones of the input signals (e.g., Vg1(φ≠0) to VgN(φ≠0)) at the given time.

In conjunction with the operation 703, the method includes an operation 705 for determining an amount of phase-shift (φ) for the phase-shifted ones of the input signals (e.g., Vg1(φ≠0) to VgN(φ≠0)) to the RF inverters (e.g., 101-1 to 101-N) that causes the combined output power of the plurality of RF inverters (e.g., 101-1 to 101-N) to approximately match the target RF power setpoint (RFsp). In some embodiments, approximately matching the target RF power setpoint (RFsp) is having the combined output power of the plurality of RF inverters (e.g., 101-1 to 101-N) be within about 10% of the target RF power setpoint (RFsp), or within about 5% of the target RF power setpoint (RFsp), or within about 3% of the target RF power setpoint (RFsp), or within about 1% of the target power setting (RFsp). In some embodiments, operations 703 and 705 include the controller (e.g., 121) operating to access a database or lookup table that provides output RF power range data for various operation modes of the RF power supply system (e.g., 100/100A) as a function of the impedance (X, R) of the plasma load 115 to determine an operation mode corresponding to the target RF power setpoint (RFsp). From the operation 705, the method proceeds with an operation 707 for directing the RF power supply system (e.g., 100/100A) to operate in accordance with the operation mode determined in operation 703 and with the amount of phase-shift (φ) determined in operation 705 applied to the phase-shifted ones of the input signals (e.g., Vg1 to VgN) that are supplied to the RF inverters (e.g., 101-1 to 101-N). In some embodiments, the RF power supply system (e.g., 100/100A) is connected to deliver RF power to an antenna (e.g., 113) of a plasma processing chamber (e.g., 116) to generate a plasma (e.g., 115A) within the plasma processing chamber (e.g., 116).

FIG. 7B shows a continuation of the method of FIG. 7A, in accordance with some embodiments. The method includes an operation 709 for measuring the combined output power of the plurality of RF inverters (e.g., 101-1 to 101-N). In some embodiments, a sensor (e.g., 110) is used to measure the combined output power of the plurality of RF inverters (e.g., 101-1 to 101-N) in real-time and transmit the measurement of the combined output power of the plurality of RF inverters (e.g., 101-1 to 101-N) to the controller (e.g., 121). In this manner, the measurement of the combined output power of the plurality of RF inverters (e.g., 101-1 to 101-N) is used as a feedback signal to regulate the combined output power of the plurality of RF inverters (e.g., 101-1 to 101-N) to match the target RF power setpoint (RFsp). From the operation 709, the method proceeds with an operation 711 for determining a phase-shift adjustment (Δφ) that reduces a difference between the measured combined output power of the plurality of RF inverters (e.g., 101-1 to 101-N) and the target RF power setpoint (RFsp). From the operation 711, the method proceeds with an operation 713 for applying the phase-shift adjustment (Δφ) to the amount of phase-shift (φ) for the phase-shifted ones of the input signals (e.g., Vg1 to VgN) to the RF inverters (e.g., 101-1 to 101-N). From the operation 713, the method proceeds with an operation 715 for repeating the sequential set of operations 709, 711, and 713 to achieve and maintain a substantial match between the combined output power of the plurality of RF inverters (e.g., 101-1 to 101-N) and the target RF power setpoint (RFsp). It should be understood that the method of FIG. 7B constitutes a closed-loop feedback control loop implemented by the controller (e.g., 121). Also, when the RF power supply system (e.g., 100/100A) is operating in a pulsed mode, the controller (e.g., 121) is programmed to use the operation mode settings that exist at the end of a previous operational pulse period at the beginning of the next operational pulse period.

FIG. 7C shows a further continuation of the methods of FIGS. 7A and 7B, in accordance with some embodiments. The method includes an operation 717 for determining that no further phase-shift adjustment (Δφ) is possible to further reduce a non-zero absolute magnitude of the difference between the measured combined output power of the plurality of RF inverters (e.g., 101-1 to 101-N) and the target RF power setpoint (RFsp) in the extant operation mode of the RF power supply system (e.g., 100/100A). From the operation 717, the method proceeds with an operation 719 for changing the operation mode of the RF power supply system (e.g., 100/100A) to another viable operation mode that provides another RF power output range for the RF power supply system (e.g., 100/100A) that includes the target RF power setpoint (RFsp). The changing of the operation mode in operation 719 is done in response to determining that no further phase-shift adjustment (Δφ) is possible in the extant operation mode of the RF power supply system (e.g., 100/100A) in operation 717. In some embodiments, the amount of phase-shift (φ) for the phase-shifted ones of the input signals (e.g., Vg1 to VgN) to the RF inverters (e.g., 101-1 to 101-N) is about 180 degrees when no further phase-shift adjustment (Δφ) is possible, and the other viable operation mode has less of the plurality of RF inverters (e.g., 101-1 to 101-N) operating (ON) as compared to the extant operation mode that is being changed from. Also, in some embodiments, the amount of phase-shift (φ) for the phase-shifted ones of the input signals (e.g., Vg1 to VgN) to the RF inverters (e.g., 101-1 to 101-N) is about zero degree when no further phase-shift adjustment (Δφ) is possible, and the other viable operation mode has more of the plurality of RF inverters (e.g., 101-1 to 101-N) operating (ON) as compared to the extant operation mode that is being changed from. In some embodiments, operation 719 includes the controller (e.g., 121) operating to access a database or lookup table that provides output RF power range data for various operation modes of the RF power supply system (e.g., 100/100A) as a function of the impedance (X, R) of the plasma load 115 to determine an operation mode corresponding to the target RF power setpoint (RFsp).

In accordance with the foregoing, example embodiments are disclosed herein for an RF power supply system (e.g., 100/100A) that includes a plurality of RF inverters (e.g., 101-1 to 101-N), where each of the plurality of RF inverters (e.g., 101-1 to 101-N) is configured to generate a sinusoidal RF signal (e.g., Vs1 to VsN) from an input signal (e.g., Vg1 to VgN) applied to one or more gates (e.g., 127) of one or more transistor devices (e.g., 125). The RF power supply system (e.g., 100/100A) includes a controller (e.g., 121) programmed to control an operation mode of the RF power supply system (e.g., 100/100A) at a given time. The operation mode is defined by which of the plurality of RF inverters (e.g., 101-1 to 101-N) are operating (ON) at the given time, which of the plurality of RF inverters (e.g., 101-1 to 101-N) are not operating (OFF) at the given time, and which of the plurality of RF inverters (e.g., 101-1 to 101-N) are operated in accordance with a phase-shifted input signal (e.g., Vg1(φ≠0) to VgN(φ≠0)) at the given time. The controller (e.g., 121) is programmed to control an amount of phase-shift (φ) applied to the phase-shifted input signal (e.g., Vg1(φ) to VgN(φ)) at the given time to cause a combined output power of the plurality of RF inverters (e.g., 101-1 to 101-N) to substantially match a target power setting, i.e., the target RF power setpoint (RFsp). In some embodiments, the RF power supply system (e.g., 100/100A) is connected to deliver RF power to an antenna (e.g., 113) of a plasma processing chamber (e.g., 116) to generate a plasma (e.g., 115A) within the plasma processing chamber (e.g., 116).

The controller (e.g., 121) is programmed to determine one of multiple viable operation modes of the RF power supply system (e.g., 100/100A) that is capable of providing an RF power output range for the RF power supply system (e.g., 100/100A) that includes the target power setting (RFsp). In some embodiments, the determined one of the multiple viable operation modes provides for a larger adjustability range in the combined output power of the plurality of RF inverters (e.g., 101-1 to 101-N) from the target power setting (RFsp) relative to others of the multiple viable operation modes. In some embodiments, the determined one of the multiple viable operation modes is dependent upon an impedance of a load (e.g., plasma load 115) to which the RF power supply system (e.g., 100/100A) is delivering RF power. In some embodiments, the determined one of the multiple viable operation modes includes multiple ones of the plurality of RF inverters (e.g., 101-1 to 101-N) operating in accordance with a non-phase-shifted input signal (φ=0) at the given time and multiple ones of the plurality of RF inverters (e.g., 101-1 to 101-N) operating in accordance with the phase-shifted input signal (φ≠0) at the given time.

In some embodiments, the controller (e.g., 121) is programmed to use a stored set of RF power versus phase-shift angle data for the determined operation mode of the RF power supply system (e.g., 100/100A) to determine an initial amount of phase-shift (φ) applied to the phase-shifted input signal (e.g., Vg1(φ) to VgN(φ)) to the RF inverters (e.g., 101-1 to 101-N) that causes the combined output power of the plurality of RF inverters (e.g., 101-1 to 101-N) to initially approximately match the target power setting (RFsp). In some embodiments, a sensor (e.g., 110) is connected to measure the combined output power of the plurality of RF inverters (e.g., 101-1 to 101-N), where the sensor (e.g., 110) is connected to transmit a signal to the controller (e.g., 121) indicating a measured combined output power of the plurality of RF inverters (e.g., 101-1 to 101-N). In some embodiments, the controller (e.g., 121) is programmed to use the signal received from the sensor (e.g., 110) as a feedback signal in a negative feedback control loop to control the amount of phase-shift (φ) applied to the phase-shifted input signal (e.g., Vg1(φ) to VgN(φ)) at the given time to ensure that the combined output power of the plurality of RF inverters (e.g., 101-1 to 101-N) substantially and continuously matches the target power setting (RFsp). In some embodiments, the controller (e.g., 121) is programmed to determine that no further phase-shift adjustment (Δφ) is possible to further reduce a non-zero absolute magnitude of the difference between the measured combined output power of the plurality of RF inverters (e.g., 101-1 to 101-N) and the target power setting (RFsp). And, in response to determining that no further phase-shift adjustment (Δφ) is possible in the extant operation mode, the controller (e.g., 121) is programmed to change the operation mode of the RF power supply system (e.g., 100/100A) to another one of the multiple viable operation modes that provides another RF power output range for the RF power supply system (e.g., 100/100A) that includes the target power setting (RFsp).

The RF power supply system (e.g., 100/100A) and controller (e.g., 121) disclosed herein provide for automatic regulation of the output power of a multilevel outphasing RF power amplifier driving a plasma load in accordance with a specified target power setting (RFsp). The RF power supply system (e.g., 100/100A) and controller (e.g., 121) disclosed herein provide for driving of the plasma load when the plasma load varies dynamically and widely in impedance by implementing frequency modulation, multilevel on/off power modulation, and outphasing power modulation, all of which are automatically controlled in a closed-loop manner by the controller (e.g., 121). In some embodiments, the controller (e.g., 121) directs adjustment of the RF power supply system (e.g., 100/100A) operation frequency (e.g., the frequency (f) of the input signal Vg1 to VgN) to reduce the variation in the impedance of the plasma load 115 by minimizing the phase angle difference between the voltage and the current at the output of the RF power supply system (e.g., 100/100A). The controller (e.g., 121) is programmed to automatically determine an operation mode for the RF power supply system (e.g., 100/100A) by determining how many of the RF inverters (e.g., 101-1 to 101-N) are to be turned ON, how many RF inverters (e.g., 101-1 to 101-N) are to be turned OFF, and what phase-shift (φ) is to be applied to phase-shifted ones of the input signals (e.g., Vg1(φ) to VgN(φ)) at a given time in order to have the output RF power of the RF power supply system (e.g., 100/100A) substantially match the target RF power setpoint (RFsp). The controller (e.g., 121) is further programmed to automatically direct phase-shift adjustment (Δφ) of the phase-shifted ones of the input signals (e.g., Vg1(φ) to VgN(φ)) in real-time as needed to regulate the output RF power of the RF power supply system (e.g., 100/100A) to substantially and continuously match the target RF power setpoint (RFsp). The controller (e.g., 121) is further programmed to dynamically and automatically change in real-time how many of the RF inverters (e.g., 101-1 to 101-N) are turned ON, how many RF inverters (e.g., 101-1 to 101-N) are turned OFF, and what phase-shift (φ) is applied to phase-shifted ones of the input signals (e.g., Vg1(φ) to VgN(φ)) in order to maintain the output RF power of the RF power supply system (e.g., 100/100A) at the target RF power setpoint (RFsp). The RF power supply system (e.g., 100/100A) and controller (e.g., 121) disclosed herein combine multilevel outphasing regulation with frequency modulation to compress the impedance range of the plasma load (e.g., 115), and in doing so provide for driving of the plasma load (e.g., 115) of widely varying impedance over a wide power range (e.g., from 0 W to several kW, or more), while maintaining high power conversion efficiency.

The various embodiments described herein may be practiced in conjunction with various computer system configurations including hand-held hardware units, microprocessor systems, microprocessor-based or programmable consumer electronics, minicomputers, mainframe computers and the like. The various embodiments described herein can also be practiced in conjunction with distributed computing environments where tasks are performed by remote processing hardware units that are linked through a computer network. It should also be understood that the various embodiments disclosed herein include performance of various computer-implemented operations involving data stored in computer systems. These computer-implemented operations are those that manipulate physical quantities. In various embodiments, the computer-implemented operations are performed by either a general purpose computer or a special purpose computer. In some embodiments, the computer-implemented operations are performed by a selectively activated computer, and/or are directed by one or more computer programs stored in a computer memory or obtained over a computer network. When computer programs and/or digital data is obtained over the computer network, the digital data may be processed by other computers on the computer network, e.g., a cloud of computing resources. The computer programs and digital data are stored as computer-readable code on a non-transitory computer-readable medium. The non-transitory computer-readable medium is any data storage hardware unit, e.g., a memory device, etc., that stores data, which is thereafter readable by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), digital video/versatile disc (DVD), magnetic tapes, and other optical and non-optical data storage hardware units. In some embodiments, the computer programs and/or digital data are distributed among multiple computer-readable media located in different computer systems within a network of coupled computer systems, such that the computer programs and/or digital data is executed and/or stored in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A radiofrequency (RF) power supply system, comprising:
a plurality of RF inverters, each of the plurality of RF inverters configured to generate a sinusoidal RF signal from an input signal applied to one or more gates of one or more transistor devices; and
a controller programmed to control an operation mode of the RF power supply system at a given time, the operation mode defined by which of the plurality of RF inverters are on at the given time, which of the plurality of RF inverters are off at the given time, and which of the plurality of RF inverters are operated in accordance with a phase-shifted input signal at the given time, the controller programmed to control an amount of phase-shift applied to the phase-shifted input signal at the given time to cause a combined output power of the plurality of RF inverters to substantially match a target power setting.

2. The RF power supply system as recited in claim 1, wherein the controller is programmed to determine one of multiple viable operation modes of the RF power supply system that provides an RF power output range for the RF power supply system that includes the target power setting.

3. The RF power supply system as recited in claim 2, wherein the determined one of the multiple viable operation modes provides for a larger adjustability range in the combined output power of the plurality of RF inverters from the target power setting relative to others of the multiple viable operation modes.

4. The RF power supply system as recited in claim 2, wherein the determined one of the multiple viable operation modes is dependent upon an impedance of a load to which the RF power supply system is delivering RF power.

5. The RF power supply system as recited in claim 2, wherein the determined one of the multiple viable operation modes includes multiple ones of the plurality of RF inverters operating in accordance with a non-phase-shifted input signal at the given time and multiple ones of the plurality of RF inverters operating in accordance with the phase-shifted input signal at the given time.

6. The RF power supply system as recited in claim 2, wherein the controller is programmed to use a stored set of RF power versus phase-shift angle data for the determined operation mode of the RF power supply system to determine an initial amount of phase-shift applied to the phase-shifted input signal to cause the combined output power of the plurality of RF inverters to initially approximately match the target power setting.

7. The RF power supply system as recited in claim 6, further comprising:
a sensor connected to measure the combined output power of the plurality of RF inverters, the sensor connected to transmit a signal to the controller indicating a measured combined output power of the plurality of RF inverters.

8. The RF power supply system as recited in claim 7, wherein the controller is programmed to use the signal received from the sensor as a feedback signal in a negative feedback control loop to control the amount of phase-shift applied to the phase-shifted input signal at the given time to cause the combined output power of the plurality of RF inverters to substantially match the target power setting.

9. The RF power supply system as recited in claim 8, wherein the controller is programmed to determine that no further phase-shift adjustment is possible to further reduce a non-zero absolute magnitude of the difference between the measured combined output power of the plurality of RF inverters and the target power setting, and in response change the operation mode of the RF power supply system to another one of the multiple viable operation modes that provides another RF power output range for the RF power supply system that includes the target power setting.

10. The RF power supply system as recited in claim 1, wherein the RF power supply system is connected to deliver RF power to an antenna of a plasma processing chamber to generate a plasma within the plasma processing chamber.

11. A method for operating a radiofrequency (RF) power supply system, comprising:
receiving a target power setting;
determining an operation mode of the RF power supply system that provides an RF power output range for the RF power supply system that includes the target power setting, the RF power supply system including a plurality of RF inverters, each of the plurality of RF inverters configured to generate a respective sinusoidal RF signal from a respective input signal applied to one or more gates of one or more respective transistor devices, the operation mode defined by which of the plurality of RF inverters are on at a given time, which of the plurality of RF inverters are off at the given time, and which of the plurality of RF inverters are operated in accordance with a phase-shifted input signal at the given time;
determining an amount of phase-shift for the phase-shifted input signal that causes a combined output power of the plurality of RF inverters to substantially match the target power setting; and
directing the RF power supply system to operate in accordance with the determined operation mode and the determined amount of phase-shift for the phase-shifted input signal.

12. The method as recited in claim 11, wherein the determined operation mode is one of multiple viable operation modes of the RF power supply system, each of the multiple viable operation modes providing a respective RF power output range for the RF power supply system that includes the target power setting, the determined operation mode providing for a larger adjustability range in the combined output power of the plurality of RF inverters from the target power setting relative to others of the multiple viable operation modes.

13. The method as recited in claim 11, further comprising:
(a) measuring the combined output power of the plurality of RF inverters;
(b) determining a phase-shift adjustment that reduces a difference between the measured combined output power of the plurality of RF inverters and the target power setting; and
(c) applying the phase-shift adjustment to the amount of phase-shift for the phase-shifted input signal.

14. The method as recited in claim 13, further comprising:
repeating (a), (b), and (c) to achieve and maintain a substantial match between the combined output power of the plurality of RF inverters and the target power setting.

15. The method as recited in claim 14, further comprising:
determining that no further phase-shift adjustment is possible to further reduce a non-zero absolute magnitude of the difference between the measured combined output power of the plurality of RF inverters and the target power setting; and
changing the operation mode of the RF power supply system to another viable operation mode that provides another RF power output range for the RF power supply system that includes the target power setting, the changing of the operation mode done in response to determining that no further phase-shift adjustment is possible.

16. The method as recited in claim 15, wherein the amount of phase-shift for the phase-shifted input signal is about 180 degrees when no further phase-shift adjustment is possible, the other viable operation mode having less of the plurality of RF inverters on as compared to the operation mode that is being changed from.

17. The method as recited in claim 15, wherein the amount of phase-shift for the phase-shifted input signal is about zero degree when no further phase-shift adjustment is possible, the other viable operation mode having more of the plurality of RF inverters on as compared to the operation mode that is being changed from.

18. The method as recited in claim 11, wherein the determined operation mode of the RF power supply system is dependent upon an impedance of a load to which the RF power supply system is delivering RF power.

19. The method as recited in claim 11, wherein the RF power supply system is connected to deliver RF power to an antenna of a plasma processing chamber to generate a plasma within the plasma processing chamber.

20. The method as recited in claim 11, wherein the determined operation mode of the RF power supply system includes multiple ones of the plurality of RF inverters operating in accordance with a non-phase-shifted input signal at the given time and multiple ones of the plurality of RF inverters operating in accordance with the phase-shifted input signal at the given time.
